(19) United States
(12) Patent Application Publication
(10) Pub. No.: US 2024/0241177 A1
(43) Pub. Date: Jul. 18, 2024

(54) METHOD AND DEVICE FOR TESTING PEAK PERFORMANCE OF MOTOR

(71) Applicants: Yu GONG, Shanghai (DE); Schaeffler Technologies AG & Co. KG, Herzogenaurach (DE)

(72) Inventors: Yu GONG, Shanghai (CN); Jiahao Li, Ningbo (CN); Liang Hu, Shanghai (CN)

(21) Appl. No.: 18/560,202

(22) PCT Filed: May 10, 2021
(86) PCT No.: PCT/CN2021/092776

§ 371 Date: Nov. 10, 2023

(51) Int. Cl. G01R 31/34

(52) U.S. Cl. CPC G01R 31/343

(57) ABSTRACT

The present disclosure provides a method and device for testing the peak performance of a motor. The method comprises: a test step of setting a maximum allowable power supply current of the motor, and testing the peak performance of the motor by using the set maximum allowable power supply current; an adjustment step of adjusting the set maximum allowable power supply current when the rotational speed of the motor reaches a predetermined rotational speed in the process of testing the performance of the motor according to the set maximum allowable power supply current, such that the current decreases with the increase of the rotational speed of the motor; and a test step of continuing to test the peak performance of the motor by using the adjusted maximum allowable power supply current. Hence, maximum copper loss density can be maintained substantially constant with the increase of the rotational speed of the motor.

### CROSS-REFERENCE TO RELATED APPLICATIONS

This application is the U.S. National Phase of PCT Appln. No. PCT/CN2021/092776, filed May 10, 2021.

### TECHNICAL FIELD

The present disclosure relates to the technical field of motors, and particularly relates to a method and device for testing peak performance of a motor.

### BACKGROUND

In related art, in certain scenarios, for example, in the scenario where users need to understand performance of a motor in order to select a suitable motor whose performance meets their needs, the performance of the motor needs to be tested before the motor leaves the factory.

Existing methods for testing the performance of a motor may only consider voltage and current limitations, however, the requirements of new energy electric vehicles for the peak performance also typically comprise a sufficient duration (10-30 seconds) at each rotational speed within an allowable temperature rise range (depending on an insulation level of a winding). Currently, most such motors use rectangular flat wires due to high slot fill rates and good quality control. However, since the rectangular flat wires have a strong skin effect at high speeds, the current density in conductors in a stator slot is severely uneven, which will lead to a higher temperature rise of the motor at high speeds. Traditional methods for estimating the peak performance may not be able to consider the higher temperature rise at high speeds.

### SUMMARY

In view of this, the present disclosure provides a method and device for testing peak performance of a motor.

In order to solve the above technical problems, according to an embodiment of the present disclosure, the method for testing the peak performance of the motor is provided, which is applied to a flat wire motor of a new energy vehicle. The method comprises: a setting and testing step of setting a maximum allowable power supply current of the motor, and testing the peak performance of the motor by using the set maximum allowable power supply current; an adjustment step of adjusting the set maximum allowable power supply current when a rotational speed of the motor reaches a predetermined rotational speed in the process of testing the performance of the motor according to the set maximum allowable power supply current, such that the current decreases with an increase of the rotational speed of the motor; and a continuous testing step of continuing to test the peak performance of the motor by using the adjusted maximum allowable power supply current.

In order to solve the above technical problems, according to another embodiment of the present disclosure, the device for testing the peak performance of the motor is provided, which is applied to the flat wire motor of the new energy vehicle. The device comprises: a setting and testing module, used for setting a maximum allowable power supply current of the motor, and testing the peak performance of the motor by using the set maximum allowable power supply current; an adjustment module, connected to the setting and testing module, and used for adjusting the set maximum allowable power supply current when a rotational speed of the motor reaches a predetermined rotational speed in the process of testing the performance of the motor according to the set maximum allowable power supply current, such that the current decreases with an increase of the rotational speed of the motor; and a continuous testing module, connected to the adjustment module, and used for continuing to test the peak performance of the motor by using the adjusted maximum allowable power supply current.

According to the method and device for testing the peak performance of the motor in the present disclosure, the peak performance of the motor is tested by using the set maximum allowable power supply current, during which if the rotational speed of the motor reaches the predetermined rotational speed, the set maximum allowable power supply current decreases with the increase of the rotational speed of the motor, and the adjusted maximum allowable power supply current is used for continuing to test the peak performance of the motor.

Therefore, compared with the prior art which only considers current and/or voltage limitations without considering the skin effect when testing the peak performance of the motor, the present disclosure not only considers the current limitation but also considers the skin effect when testing the peak performance of the motor. Hence, by decreasing the maximum allowable power supply current applied to the motor when the rotational speed of the motor reaches the predetermined rotational speed, a maximum copper loss density can be maintained substantially constant with the increase of the rotational speed of the motor.

Other features and aspects of the present disclosure will become clear according to the following detailed descriptions of exemplary embodiments with reference to drawings.

### BRIEF DESCRIPTION OF THE DRAWINGS

The drawings included in the specification and constituting a part thereof together with the specification illustrate exemplary embodiments, features, and aspects of the present disclosure, and are used to explain the principles of the present disclosure.

FIG. 1 is a flow chart of a method for testing peak performance of a motor in the related art.

FIG. 2 is a flow chart of a method for testing peak performance of a motor according to an exemplary embodiment.

FIG. 3 is an exemplary flow chart of the method for testing the peak performance of the motor according to an exemplary embodiment.

FIG. 4 is a schematic diagram of comparison of the peak performance of the motor after applying the methods for testing the peak performance of the motor in the present embodiment and the related art.

FIG. 5 is a schematic diagram of comparison of the copper loss density in last conductors of stator slots after applying the methods for testing the peak performance of the motor in the present embodiment and the related art.

FIG. 6 is a block diagram of an engine start control device for a hybrid electric vehicle illustrated according to an exemplary embodiment.

### DETAILED DESCRIPTION

Various exemplary embodiments, features and aspects of the present disclosure will be described in detail below with reference to the drawings. The same reference numerals in the drawings indicate elements with the same or similar functions. Although various aspects of the embodiments are shown in the drawings, the drawings are not necessarily drawn to scale unless otherwise specified.

The dedicated word “exemplary” herein means “serving as an example and an embodiment, or being illustrative”. Any embodiment described herein as “exemplary” is not necessarily construed as being superior to or better than other embodiments.

In addition, in order to better illustrate the present disclosure, numerous specific details are given in the following specific embodiments. Those skilled in the art will understand that the present disclosure can also be implemented without certain specific details. In some other examples, the methods, means, elements and circuits that are well known to those skilled in the art have not been described in detail, so as to highlight the gist of the present disclosure.

It should be understood that conductors will be affected by a skin effect. When there is an alternating current or alternating electromagnetic field in conductors, the current inside the conductors is unevenly distributed, and the current is concentrated in “skin” parts of the conductors, that is to say, the current is concentrated in thin layers on the surfaces of the conductors, the closer to the surfaces of the conductors, the greater the current density, and the current inside a wire is actually small, which results in an increase in the resistance of the conductors and an increase in power loss of the conductors. This phenomenon can be called the skin effect. It is obvious that the skin effect causes a great waste of current, and incapability of efficient utilization also causes a great waste of energy.

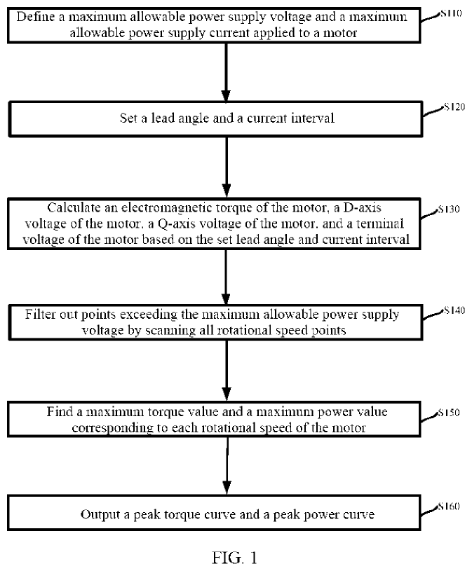

FIG. 1 is a flow chart of a method for testing peak performance of a motor in the related art. In the related art, the peak performance of the motor can be tested by the method for testing the peak performance of the motor as shown in FIG. 1. The method for testing the peak performance comprises:

In step S110, a maximum allowable power supply voltage (Uₘ) and a maximum allowable power supply current (Iₘ) applied to the motor are defined according to a battery capacity and a capacity of a power electronic unit (PEU for short).

In step S120, a lead angle and a current interval are set, that is, the lead angle θ and a current step size are set, wherein tan(θ)=i_{d}/i_{q}, lₛ≤lₘ, Iₛ=\sqrt{i_{d}²+i_{q}²}, i_{d} is a D-axis output current (that is, a D-axis component of a stator current), and i_{q} is a Q-axis output current (that is, a Q-axis component of the stator current).

In step S130, an electromagnetic torque (Tₑ) of the motor, a D-axis voltage (U_{d}) of the motor, a Q-axis voltage (U_{q}) of the motor, and a terminal voltage (Uₛ) of the motor are calculated based on the lead angle and the current interval set in step S120. That is, according to the set step size, the D-axis component of the stator voltage U_{d}, the Q-axis components of the stator voltage U_{q}, Uₛ, and Tₑ corresponding to each current are calculated. In one possible implementation, U_{d}, U_{q}, Uₛ, and Tₑ can be calculated by employing the following Equation 1, Equation 2, Equation 3, and Equation 4:

$${T}_{e} = \frac{3}{2} {P}_{n} {i}_{q} [ {i}_{d} ( {L}_{d} - {L}_{q} ) + {φ}_{f} ] \qquad Equation 1$$

$${U}_{d} = - {w}_{e} {L}_{q} {i}_{q} \qquad Equation 2$$

$${U}_{q} = {w}_{e} ( {L}_{d} {i}_{d} + {φ}_{f} ) \qquad Equation 3$$

$${U}_{s} = \sqrt{{U}_{d}^{2} + {U}_{q}^{2}} = \sqrt{{( {w}_{e} {L}_{q} {i}_{q} )}^{2} + {[ {w}_{e} ( {L}_{d} {i}_{d} + {φ}_{f} ) ]}^{2}} = {w}_{e} \sqrt{{( {L}_{q} {i}_{q} )}^{2} + {( {L}_{d} {i}_{d} + {φ}_{f} )}^{2}} \qquad Equation 4$$

wherein Pₙ is a number of pole pairs of the motor, La is a D-axis motor inductance, L_{q} is a Q-axis motor inductance, or is a permanent magnet flux linkage of the motor, and wₑ is an electrical angle of a first intersection point B of a maximum torque-to-voltage ratio control curve and a current limit circle of the motor.

In step S140, points exceeding the maximum allowable power supply voltage Uₘ are filtered out by scanning all rotational speed points. That is, all rotational speed points that satisfy Uₛ>Uₘ are deleted.

In step S150, a maximum torque value and a maximum power value corresponding to each rotational speed of the motor are found.

In step S160, a peak torque curve and a peak power curve are outputted. The maximum torque values of all rotational speed points can be connected into a curve, and the curve is the peak torque curve; and accordingly, the maximum power values of all rotational speed points can be connected into a curve, and the curve is the peak power curve.

However, the above method for testing the performance of the motor may only consider the voltage and current limitations, e.g., only consider the maximum allowable power supply voltage Uₘ and the maximum allowable power supply current Iₘ applied to the motor, without considering the skin effect, thereby possibly leading to an uneven current density in conductors in a stator slot.

Specifically, the requirements of new energy electric vehicles for the peak performance also typically comprise a sufficient duration (10-30 seconds) at each rotational speed of the motor within an allowable temperature rise range (depending on an insulation level of a winding). Currently, most such motors use rectangular flat wires due to high slot fill rates and good quality control. However, since rectangular flat wires have a strong skin effect at high speeds, the current density of the conductors in the stator slot is severely uneven, which will lead to a higher temperature rise of the motor at high speeds, thereby leading to the incapability of maintaining a maximum copper loss density constant with an increase of the rotational speed of the motor.

To this end, the present disclosure realizes that: in the process of testing the performance of the motor, the maximum allowable power supply current used in the process of testing the performance of the motor can decrease in the case that the rotational speed of the motor reaches a certain rotational speed value, thereby enabling the maximum copper loss density to be maintained substantially constant with the increase of the rotational speed of the motor.

Specifically, the present disclosure provides the method and device for testing the performance of the motor. The peak performance (e.g., peak torque, peak power, etc.) of the motor is tested by using the set maximum allowable power supply current, during which if the rotational speed of the motor reaches the predetermined rotational speed, the set maximum allowable power supply current is adjusted, such that the maximum allowable power supply current decreases with the increase of the rotational speed of the motor, and then the adjusted maximum allowable power supply current is used for continuing to test the peak performance of the motor.

Hence, when the peak performance of the motor is tested, not only the current limitation but also the skin effect are considered, and by decreasing the maximum allowable power supply current applied to the motor with the increase of the rotational speed of the motor, the maximum copper loss density can be maintained substantially constant with the increase of the rotational speed of the motor.

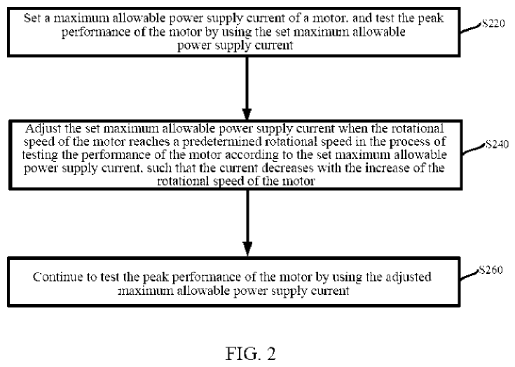

In order to better understand the present disclosure, the method for testing the performance of the motor of the present disclosure will be described in detail below in conjunction with the flow chart shown in FIG. 2.

FIG. 2 is a flow chart of the method for testing the performance of the motor according to an exemplary embodiment. The method for testing the performance of the motor can be applied to a flat wire motor of a new energy vehicle, wherein the flat wire motor may refer to a motor using flat wires, e.g., rectangular flat wires. In one implementation, the new energy vehicle may comprise a motor and a controller thereof (i.e., a motor controller), and the motor controller can test the performance of the flat wire motor of the new energy vehicle by adopting the method for testing the performance of the motor of the present disclosure. As shown in FIG. 2, the method for testing the performance of the motor may comprise the following steps.

In step S220, a maximum allowable power supply current Iₘ of the motor is set, and the peak performance of the motor is tested by using the set maximum allowable power supply current Iₘ. Step S220 corresponds to a setting and testing step.

In the present embodiment, the maximum allowable power supply current Iₘ of the motor is the maximum allowable power supply current that the motor controller can apply to the motor. It should be understood that the greater the current the motor controller applies to the motor, the shorter the duration of the current, so it is necessary to set the maximum allowable power supply current Iₘ within a specified time to limit the current outputted by the motor controller, thereby preventing a too short duration caused by an excessive current.

In one possible implementation, the motor controller may set the maximum allowable power supply current of the motor based on parameters related to the current limitation of the motor.

In the present embodiment, the parameters related to the current limitation of the motor may comprise, but be not limited to, parameters affecting the current that the motor controller can output, e.g., a battery capacity, a capacity of a power electronic unit, etc. In one possible implementation, the motor controller may set the maximum allowable power supply current Iₘ applied to the motor based on the battery capacity and the capacity of the power electronic unit as the parameters related to the current limitation of the motor.

After the maximum allowable power supply current Iₘ is set, the motor controller can test the peak performance of the motor by using the set maximum allowable power supply current Iₘ. The peak performance of the motor comprises, but is not limited to, a peak torque and a peak power. Testing the peak performance of the motor may comprise, but be not limited to, outputting a curve or a distribution histogram, etc. corresponding to the peak performance of the motor, so that a user can more conveniently view the peak performance of the motor.

Exemplarily, a peak torque curve may be a peak torque curve formed by connecting multiple points with the rotational speeds of the motor as the abscissa and the maximum torque values of the motor as the ordinate, or a peak torque distribution histogram drawn based on the rotational speeds and the maximum torque values corresponding thereto. Accordingly, a peak power curve may be a peak power curve formed by connecting multiple points with the rotational speeds of the motor as the abscissa and the maximum power values of the motor as the ordinate, or a peak power distribution histogram drawn based on the rotational speeds and the maximum power values corresponding thereto.

In step S240, the set maximum allowable power supply current Iₘ is adjusted when the rotational speed of the motor n reaches a predetermined rotational speed n_{b} in the process of testing the performance of the motor according to the set maximum allowable power supply current Iₘ, such that the current decreases with the increase of the rotational speed of the motor. Step S240 corresponds to an adjustment step.

In the present embodiment, in the process of testing the peak performance of the motor according to the set maximum allowable power supply current Iₘ in above step S220, the motor controller may obtain the rotational speed of the motor n. In one possible implementation, the motor controller may obtain the rotational speed of the motor through, for example, a rotational speed sensor arranged on the motor.

The motor controller may judge whether the obtained rotational speed n reaches the predetermined rotational speed n_{b}. In one possible implementation, the motor controller may compare the obtained rotational speed n with the predetermined rotational speed n_{b}. If the obtained rotational speed n is greater than or equal to the predetermined rotational speed n_{b}, the motor controller judges that the obtained rotational speed n has reached the predetermined rotational speed n_{b}.

The setting manners of the predetermined rotational speed n_{b} comprise, but are not limited to, setting based on actual test results or setting based on experience of engineers. In one possible implementation, the rotational speed of the motor when the actually measured copper loss density reaches the maximum allowable value may be set as the predetermined rotational speed n_{b}. Specifically, if it is found through actual testing that at a certain rotational speed, a short-term temperature rise reaches the maximum allowable value, the copper loss density at the time reaches the maximum allowable value, and the rotational speed at the time may be set as the predetermined rotational speed n_{b}. In another possible implementation, the predetermined rotational speed set by the engineers based on the experience may be obtained and used as the predetermined rotational speed n_{b}.

In the case that it is judged that the obtained rotational speed n has reached the predetermined rotational speed n_{b}, it means that the copper loss density at the time has reached the maximum allowable value. In this case, the motor controller needs to decrease the set maximum allowable power supply current Iₘ to maintain the copper loss density substantially unchanged. In other words, in the above case, the motor controller may adjust the set maximum allowable power supply current Iₘ in step S220 in an adjustment manner that the set maximum allowable power supply current Iₘ in above step S220 decreases with the increase of the rotational speed n of the motor. The adjusted maximum allowable power supply current is I′ₘ.

It should be understood that in the case that it is judged that the obtained rotational speed n has reached the predetermined rotational speed n_{b}, the motor controller may decrease the maximum allowable power supply current according to the rotational speed n of the motor. The present disclosure does not impose specific restrictions on how to decrease the maximum allowable power supply current and/or what value the maximum allowable power supply current decreases to. Any decreasing manner and any value allowing to decrease the maximum allowable power supply current to enable the copper loss density to be maintained substantially constant can be applied to the present disclosure.

In one possible implementation, the maximum allowable power supply current may be decreased by the following manners: calculating a ratio of the height of conductors in a stator slot of the motor to the skin depth; calculating a target maximum allowable power supply current based on the ratio, identification of the conductors, and the set maximum allowable power supply current; and adjusting the set maximum allowable power supply current to the calculated target maximum allowable power supply current, wherein the target maximum allowable power supply current is less than the set maximum allowable power supply current.

In the present embodiment, as mentioned above, when the rotational speed of the motor reaches the predetermined rotational speed, the maximum copper loss density will be unable to maintain constant with the increase of the rotational speed of the motor due to the skin effect. Therefore, in order to maintain the maximum copper loss density substantially constant, the skin effect needs to be considered when the rotational speed of the motor reaches the predetermined rotational speed. Therefore, the motor controller may obtain the height of the conductors in the stator slot and the skin depth corresponding thereto, and calculate the ratio of the two.

Corresponding conductors are disposed at corresponding positions of the stator slot, and the conductors disposed at different positions have different kinds of identification. Therefore, the identification of the conductors may also indicate the positions of the conductors in the stator slot. It should be understood that the skin depth may represent the depth at which the current density in the conductors decreases to 1/e (e is the natural base e=2.71828183) of the current density on the surfaces of the cross sections of the conductors, which is not limited in the present disclosure and depends on the specific situation.

The motor controller may calculate a decreasing amplitude (also referred to as a decreasing coefficient) based on the calculated ratio of the height of the conductors to the skin depth and the identification of the conductors, and may apply the decreasing amplitude to the set maximum allowable power supply current in step S220 to decrease the maximum allowable power supply current.

In one implementation, the maximum allowable power supply current may decrease by performing a multiplication operation on the decreasing amplitude and the set maximum allowable power supply current in step S220, and in this case, the decreasing amplitude should be less than 1; the maximum allowable power supply current may also decrease by performing a subtraction operation on the decreasing amplitude and the set maximum allowable power supply current in step S220; and the maximum allowable power supply current may also decrease by performing a division operation on the decreasing amplitude and the set maximum allowable power supply current in step S220, and in this case, the decreasing amplitude should be greater than 1.

Of course, it should be understood that the decreasing amplitude may also be applied to the set maximum allowable power supply current in step S220 by any other suitable algorithm, as long as the maximum allowable power supply current can decrease by adopting the algorithm.

In one possible implementation, based on the ratio of the height of the conductors in the stator slot of the motor to the skin depth, the identification of the conductors, and the set maximum allowable power supply current, the target maximum allowable power supply current can be calculated by employing the following equations:

$${I}_{m} = \frac{{I}_{b}}{\sqrt{φ ( ξ ) + N ( N - 1 ) ψ ( ξ )}} , \qquad ( Equation 5 )$$

$$φ ( ξ ) = ξ \frac{s h ( 2 ξ ) + sin ( 2 ξ )}{c h ( 2 ξ ) - cos ( 2 ξ )} , \qquad ( Equation 6 )$$

$$ψ ( ξ ) = 2 ξ \frac{s h ( ξ ) - sin ( ξ )}{c h ( ξ ) + cos ( ξ )} , \qquad ( Equation 7 )$$

wherein Iₘ represents the target maximum allowable power supply current, I_{b} represents the set maximum allowable power supply current, ξ represents the ratio of the height of the conductors to the skin depth, and N represents the identification of the conductors.

In step S260, the adjusted maximum allowable power supply current is used for continuing to test the peak performance of the motor. Step S260 corresponds to a continuous testing step.

In the present embodiment, before the rotational speed of the motor reaches the predetermined rotational speed, the motor controller can test the peak performance of the motor by using the set maximum allowable power supply current in step S220. When the rotational speed of the motor reaches the predetermined rotational speed, the motor controller adjusts the set maximum allowable power supply current in step S220 to decrease it, and then the motor controller can use the adjusted maximum allowable power supply current for continuing to test the peak performance of the motor.

According to the method for testing the performance of the motor in the present embodiment, the peak performance of the motor is tested by using the set maximum allowable power supply current, during which if the rotational speed of the motor reaches the predetermined rotational speed, the set maximum allowable power supply current decreases with the increase of the rotational speed of the motor, and the adjusted maximum allowable power supply current is used for continuing to test the peak performance of the motor. Therefore, compared with the prior art which only considers the current limitation and/or voltage limitation without considering the skin effect when testing the peak performance of the motor, the present embodiment considers not only the current limitation but also the skin effect when testing the peak performance of the motor. Hence, by decreasing the maximum allowable power supply current applied to the motor when the rotational speed of the motor reaches the predetermined rotational speed, the maximum copper loss density can be maintained substantially constant with the increase of the rotational speed of the motor.

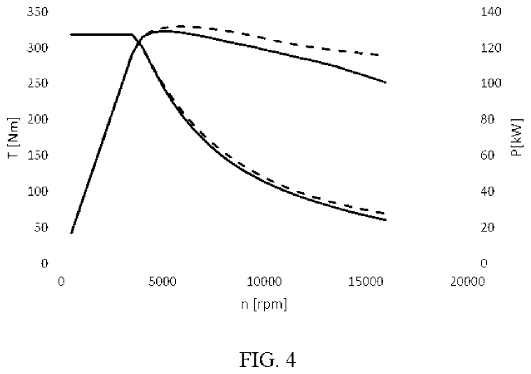

FIG. 4 is a schematic diagram of comparison of the peak performance of the motor after applying the methods for testing the peak performance of the motor in the present embodiment and the related art. In FIG. 4, the symbols “T”, “P” and “n” represent the peak torque, the peak power and the rotational speed, respectively, the solid line represents a curve obtained by testing the peak performance of the motor adopting the method for testing the peak performance of the motor in the present embodiment, and the dotted line represents a curve obtained by testing the peak performance of the motor adopting the method for testing the peak performance of the motor in the prior art.

As shown in FIG. 4, before the rotational speed of the motor reaches 5000 rpm, the peak torque obtained by adopting the method for testing the peak performance of the motor in the present embodiment is substantially consistent with the peak torque obtained by adopting the method for testing the peak performance of the motor in the prior art, and the peak power obtained by adopting the method for testing the peak performance of the motor in the present embodiment is also substantially consistent with the peak power obtained by adopting the method for testing the peak performance of the motor in the prior art. However, when the rotational speed of the motor reaches 5000 rpm, at the same rotational speed point, the peak torque obtained by adopting the method for testing the peak performance of the motor in the present embodiment is smaller than the peak torque obtained by adopting the method for testing the peak performance of the motor in the prior art, and the peak power obtained by adopting the method for testing the peak performance of the motor in the present embodiment is also smaller than the peak power obtained by adopting the method for testing the peak performance of the motor in the prior art.

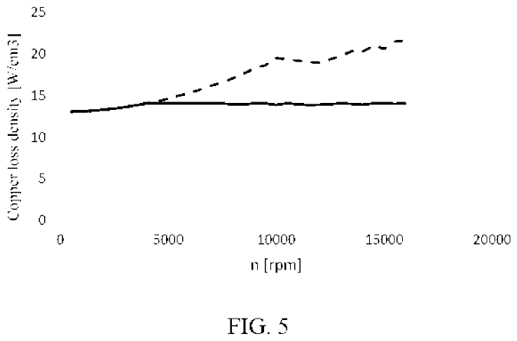

FIG. 5 is a schematic diagram of comparison of the copper loss density in last conductors of stator slots after applying the methods for testing the peak performance of the motor in the present embodiment and the related art. In FIG. 5, the symbol “n” represents the rotational speed, the solid line represents a curve obtained by testing the peak performance of the motor adopting the method for testing the peak performance of the motor in the present embodiment, and the dotted line represents a curve obtained by testing the peak performance of the motor adopting the method for testing the peak performance of the motor in the prior art.

As shown in FIG. 5, before the rotational speed of the motor reaches 5000 rpm, the copper loss density in the last conductor of the stator slot obtained by adopting the methods for testing the peak performance of the motor in the present embodiment and the prior art are substantially consistent. However, when the rotational speed of the motor reaches 5000 rpm, the copper loss density in the last conductor of the stator slot obtained by adopting the method for testing the peak performance of the motor in the prior art increases with the increase of the rotational speed, while the copper loss density in the last conductor of the stator slot obtained by adopting the method for testing the peak performance of the motor in the present embodiment is maintained substantially constant with the increase of the rotational speed.

In one possible implementation, the above setting and testing step may comprise: setting the maximum allowable power supply current of the motor and the maximum allowable power supply voltage of the motor; calculating the electromagnetic torque and the phase voltage of the motor corresponding to each rotational speed of the motor according to the set lead angle and current test step size; and filtering out the electromagnetic torque and phase voltage corresponding to the rotational speed at which the phase voltage exceeds the maximum allowable power supply voltage.

In the present embodiment, the motor controller may test the peak performance of the motor by using the set maximum allowable power supply current by adopting the related method shown in FIG. 1. Exemplarily, in addition to setting the maximum allowable power supply current, the maximum allowable power supply voltage of the motor may also be set; the lead angle and the current test step size may be set; the electromagnetic torque and the phase voltage of the motor corresponding to each rotational speed of the motor may be calculated according to the set lead angle and current test step size; and rotational speed points with voltage exceeding the maximum allowable power supply voltage are filtered out by scanning all rotational speed points. For detailed description, please refer to the previous description about steps S110-S140. Due to space limitations, details will not be repeated here.

In one possible implementation, the adjustment step may comprise: after the electromagnetic torque and the phase voltage corresponding to the rotational speed at which the phase voltage exceeds the maximum allowable power supply voltage are filtered out, when the rotational speed of the motor reaches the predetermined rotational speed, enabling the set maximum allowable power supply current to decrease with the increase of the rotational speed of the motor.

In the present embodiment, the motor controller may, for example, scan all rotational speed points to filter out the electromagnetic torque and the phase voltage corresponding to the rotational speed point with the phase voltage exceeding the maximum allowable power supply voltage Uₘ. For the remaining rotational speed points after filtering, the set maximum allowable power supply current in step S220 is adjusted by adopting a manner of above step S240.

In one possible implementation, the continuous testing step may comprise: generating a peak torque curve of the motor representing the peak torque performance of the motor based on the maximum electromagnetic torque (i.e., peak torque) corresponding to each remaining rotational speed; and generating a peak power curve of the motor representing the peak power performance of the motor based on the maximum power (i.e., peak power) corresponding to each remaining rotational speed.

In the present embodiment, multiple points of the peak torque corresponding to each remaining rotational speed can be connected, thereby forming the peak torque curve; accordingly, multiple points of the peak power corresponding to each remaining rotational speed can be connected, thereby forming the peak power curve; and a user can know the peak performance of the motor based on the peak torque curve and the peak power curve.

In one possible implementation, the setting and testing step may comprise: setting the maximum allowable power supply voltage and the maximum allowable power supply current of the motor based on the current and voltage capacities of a battery and a power control unit PEU of the new energy vehicle. For details, please refer to the previous description about step S110. Due to space limitations, details will not be repeated here.

In one possible implementation, calculating the phase voltage corresponding to each rotational speed of the motor comprises: obtaining a D-axis output voltage and a Q-axis output voltage under a rotational coordinate system corresponding to each rotational speed of the motor; and calculating the phase voltage corresponding to each rotational speed based on the obtained D-axis output voltage and Q-axis output voltage corresponding to each rotational speed.

Exemplarily, the motor controller may obtain the D-axis output voltage and the Q-axis output voltage respectively by employing Equation 2 and Equation 3, and then calculate the corresponding phase voltage by employing Equation 4.

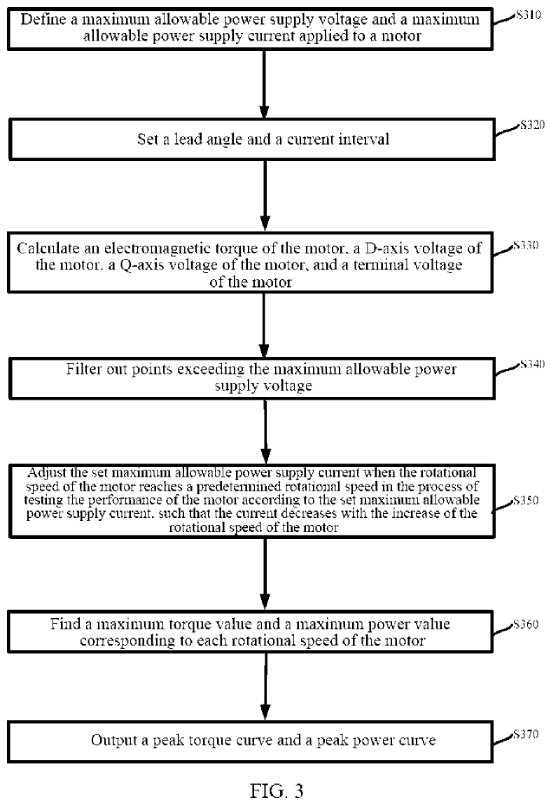

The following description acts as a specific example of the method for testing the peak performance of the motor in the present embodiment. FIG. 3 is an exemplary flow chart of the method for testing the peak performance of the motor according to an exemplary embodiment. As shown in FIG. 3, the method for testing the peak performance of the motor may comprise:

In step S310, the maximum allowable power supply voltage and the maximum allowable power supply current applied to the motor are defined. For details about this step, please refer to the previous description about steps S110 and S220. Due to space limitations, details will not be repeated here.

In step S320, the lead angle and current interval are set. For details about this step, please refer to the previous description about steps S120 and S220. Due to space limitations, details will not be repeated here.

In step S330, the electromagnetic torque of the motor, the D-axis voltage of the motor, the Q-axis voltage of the motor, and the terminal voltage of the motor are calculated. For details about this step, please refer to the previous description about steps S130 and S220. Due to space limitations, details will not be repeated here.

In step S340, points exceeding the maximum allowable power supply voltage are filtered out. For details about this step, please refer to the previous description about steps S140 and S220. Due to space limitations, details will not be repeated here.

In step S350, the set maximum allowable power supply current is adjusted when the rotational speed of the motor reaches a predetermined rotational speed in the process of testing the performance of the motor according to the set maximum allowable power supply current, such that the current decreases with the increase of the rotational speed of the motor. For details about this step, please refer to the previous description about step S240. Due to space limitations, details will not be repeated here.

In step S360, a maximum torque value and a maximum power value corresponding to each rotational speed of the motor are found. For details about this step, please refer to the previous description about steps S150 and S220. Due to space limitations, details will not be repeated here.

In step S370, a peak torque curve and a peak power curve are outputted. For details about this step, please refer to the previous description about steps S160 and S220. Due to space limitations, details will not be repeated here.

By comparing FIG. 1 with FIG. 3, it can be seen that compared with the prior art, in the method for testing the performance of the motor in the present embodiment, step S350 of enabling the set maximum allowable power supply current to decrease with the increase of the rotational speed of the motor when the rotational speed of the motor reaches the predetermined speed is added. Therefore, it can be ensured that the maximum copper loss density can be maintained substantially constant with the increase of the rotational speed of the motor when the motor is running at high speeds, thereby avoiding the influence of the skin effect.

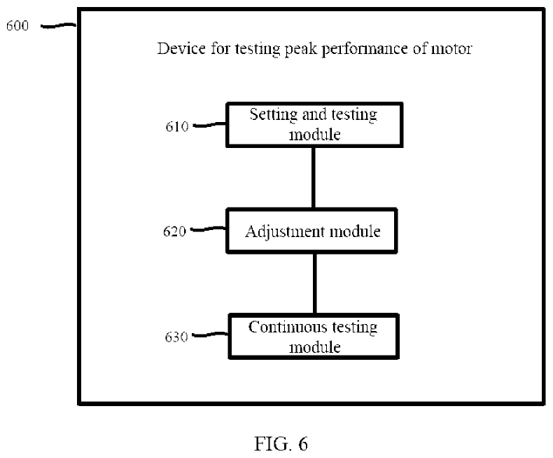

FIG. 6 is a block diagram of the device for testing the peak performance of the motor shown by an exemplary embodiment. The device for testing the peak performance of the motor can be applied to the flat wire motor of the new energy vehicle. As shown in FIG. 6, the device for testing the peak performance of the motor 600 may comprise a setting and testing module 610, an adjustment module 620, and a continuous testing module 630.

The setting and testing module 610 is used for setting a maximum allowable power supply current of the motor, and testing the peak performance of the motor by using the set maximum allowable power supply current. The adjustment module 620 is connected to the setting and testing module 610, and used for adjusting the set maximum allowable power supply current when the rotational speed of the motor reaches a predetermined rotational speed in the process of testing the performance of the motor according to the set maximum allowable power supply current, such that the current decreases with the increase of the rotational speed of the motor. The continuous testing module 630 is connected to the adjustment module 620, and used for continuing to test the peak performance of the motor by using the adjusted maximum allowable power supply current.

In one possible implementation, the adjustment module 620 is configured to: calculate a ratio of the height of conductors in a stator slot of the motor to the skin depth; calculate a target maximum allowable power supply current based on the ratio, identification of the conductors, and the set maximum allowable power supply current; and adjust the set maximum allowable power supply current to the calculated target maximum allowable power supply current, wherein the target maximum allowable power supply current is less than the set maximum allowable power supply current.

In one possible implementation, the adjustment module 620 is configured to: based on the ratio, the identification of the conductors, and the set maximum allowable power supply current, calculate the target maximum allowable power supply current by employing the following equations:

$${I}_{m} = \frac{{I}_{b}}{\sqrt{φ ( ξ ) + N ( N - 1 ) ψ ( ξ )}} ,$$

$$φ ( ξ ) = ξ \frac{s h ( 2 ξ ) + sin ( 2 ξ )}{c h ( 2 ξ ) - cos ( 2 ξ )} , and$$

$$ψ ( ξ ) = 2 ξ \frac{s h ( ξ ) - sin ( ξ )}{c h ( ξ ) + cos ( ξ )} ,$$

wherein Iₘ represents the target maximum allowable power supply current, I_{b} represents the set maximum allowable power supply current, ξ represents the ratio of the height of the conductors to the skin depth, and N represents the identification of the conductors.

In one possible implementation, the setting and testing module 610 is configured to: set the maximum allowable power supply current of the motor and the maximum allowable power supply voltage of the motor; calculate the electromagnetic torque and the phase voltage of the motor corresponding to each rotational speed of the motor according to the set lead angle and current test step size; and filter out the electromagnetic torque and the phase voltage corresponding to the rotational speed at which the phase voltage exceeds the maximum allowable power supply voltage.

In one possible implementation, the adjustment module 620 is configured to: after the electromagnetic torque and the phase voltage corresponding to the rotational speed at which the phase voltage exceeds the maximum allowable power supply voltage are filtered out, when the rotational speed of the motor reaches the predetermined rotational speed, enabling the set maximum allowable power supply current to decrease with the increase of the rotational speed of the motor.

In one possible implementation, the continuous testing module 630 is configured to: generate a peak torque curve of the motor representing the peak torque performance of the motor based on the maximum electromagnetic torque corresponding to each remaining rotational speed; and generate a peak power curve of the motor representing the peak power performance of the motor based on the maximum power corresponding to each remaining rotational speed.

In one possible implementation, the setting and testing module 610 is configured to: set the maximum allowable power supply voltage and the maximum allowable power supply current of the motor based on the current and voltage capacities of a battery and a power control unit PEU of the new energy vehicle.

In one possible implementation, the setting and testing module 610 is configured to: obtain a D-axis output voltage and a Q-axis output voltage under a rotational coordinate system corresponding to each rotational speed of the motor; and calculate the phase voltage corresponding to the rotational speed based on the obtained D-axis output voltage and Q-axis output voltage corresponding to each rotational speed.

Regarding the apparatus in the above embodiment, the specific ways in which each module executes operations have been described in detail in the embodiments related to the method, and will not be described in detail here.

The above is only specific embodiments of the present disclosure, but the protection scope of the present disclosure is not limited thereto, and any change or substitution that may be easily thought of by those skilled in the art within the technical scope disclosed by the present disclosure should be covered within the protection scope of the present disclosure. Therefore, the protection scope of the present disclosure shall be subject to the protection scope of the claims.

1. A method for testing peak performance of a motor, applied to a flat wire motor of a new energy vehicle, comprising:
a setting and testing step of setting a maximum allowable power supply current of the motor, and testing the peak performance of the motor by using the set maximum allowable power supply current;
an adjustment step of adjusting the set maximum allowable power supply current when a rotational speed of the motor reaches a predetermined rotational speed during testing the performance of the motor according to the set maximum allowable power supply current, such that the current decreases with an increase of the rotational speed of the motor; and
a continuous testing step of continuing to test the peak performance of the motor by using the adjusted maximum allowable power supply current.

2. The method for testing the peak performance of the motor according to claim 1, wherein the adjustment step includes:
calculating a ratio of a height of conductors in a stator slot of the motor to a skin depth;
calculating a target maximum allowable power supply current based on the ratio, identification of the conductors, and the set maximum allowable power supply current; and
adjusting the set maximum allowable power supply current to the calculated target maximum allowable power supply current, wherein the target maximum allowable power supply current is less than the set maximum allowable power supply current.

3. The method for testing the peak performance of the motor according to claim 2, wherein the adjustment step includes calculating, based on the ratio, the identification of the conductors, and the set maximum allowable power supply current, the target maximum allowable power supply current by employing the following equations:
$${I}_{m} = \frac{{I}_{b}}{\sqrt{φ ( ξ ) + N ( N - 1 ) ψ ( ξ )}} , φ ( ξ ) = ξ \frac{s h ( 2 ξ ) + sin ( 2 ξ )}{c h ( 2 ξ ) - cos ( 2 ξ )} , ψ ( ξ ) = 2 ξ \frac{s h ( ξ ) - sin ( ξ )}{c h ( ξ ) + cos ( ξ )} ,$$
wherein Iₘ represents the target maximum allowable power supply current, I_{b} represents the set maximum allowable power supply current, ξ represents the ratio of the height of the conductors to the skin depth, and N represents the identification of the conductors.

4. The method for testing the peak performance of the motor according claim 1, wherein the setting and testing step includes:
setting the maximum allowable power supply current of the motor and a maximum allowable power supply voltage of the motor;
calculating an electromagnetic torque and a phase voltage of the motor corresponding to each rotational speed of the motor according to a set lead angle and current test step size; and
filtering out the electromagnetic torque and the phase voltage corresponding to the rotational speed at which the phase voltage exceeds the maximum allowable power supply voltage.

5. The method for testing the peak performance of the motor according to claim 4, wherein the adjustment step includes:
after the electromagnetic torque and the phase voltage corresponding to the rotational speed at which the phase voltage exceeds the maximum allowable power supply voltage are filtered out, when the rotational speed of the motor reaches the predetermined rotational speed, enabling the set maximum allowable power supply current to decrease with an increase of the rotational speed of the motor.

6. The method for testing the peak performance of the motor according to claim 5, wherein the continuous testing step includes:
generating a peak torque curve of the motor representing peak torque performance of the motor based on a maximum electromagnetic torque corresponding to each remaining rotational speed; and
generating a peak power curve of the motor representing peak power performance of the motor based on a maximum power corresponding to each remaining rotational speed.

7. The method for testing the peak performance of the motor according to claim 4, wherein the setting and testing step includes:
setting the maximum allowable power supply voltage and the maximum allowable power supply current of the motor based on current and voltage capacities of a battery and a power control unit PEU of the new energy vehicle.

8. The method for testing the peak performance of the motor according to claim 4, wherein calculating the phase voltage corresponding to each rotational speed of the motor includes:
obtaining a D-axis output voltage and a Q-axis output voltage under a rotational coordinate system corresponding to each rotational speed of the motor; and
calculating the phase voltage corresponding to the rotational speed based on the obtained D-axis output voltage and Q-axis output voltage corresponding to each rotational speed.

9. A device for testing peak performance of a motor, applied to a flat wire motor of a new energy vehicle, the device comprising:
a setting and testing module, used for setting a maximum allowable power supply current of the motor, and testing the peak performance of the motor by using the set maximum allowable power supply current;
an adjustment module, connected to the setting and testing module, and used for adjusting the set maximum allowable power supply current when a rotational speed of the motor reaches a predetermined rotational speed in the process of testing the performance of the motor according to the set maximum allowable power supply current, such that the current decreases with an increase of the rotational speed of the motor; and
a continuous testing module, connected to the adjustment module, and used for continuing to test the peak performance of the motor by using the adjusted maximum allowable power supply current.

10. The device for testing the peak performance of the motor according to claim 9, wherein the adjustment module is configured to:
calculate a ratio of the height of conductors in a stator slot of the motor to the skin depth;
calculate a target maximum allowable power supply current based on the ratio, identification of the conductors, and the set maximum allowable power supply current; and
adjust the set maximum allowable power supply current to the calculated target maximum allowable power supply current, wherein the target maximum allowable power supply current is less than the set maximum allowable power supply current.

11. The device for testing the peak performance of the motor according to claim 10, wherein the adjustment module is configured to: based on the ratio, the identification of the conductors, and the set maximum allowable power supply current, calculate the target maximum allowable power supply current by employing the following equations:
$${I}_{m} = \frac{{I}_{b}}{\sqrt{φ ( ξ ) + N ( N - 1 ) ψ ( ξ )}} , φ ( ξ ) = ξ \frac{s h ( 2 ξ ) + sin ( 2 ξ )}{c h ( 2 ξ ) - cos ( 2 ξ )} , ψ ( ξ ) = 2 ξ \frac{s h ( ξ ) - sin ( ξ )}{c h ( ξ ) + cos ( ξ )} ,$$
wherein Iₘ represents the target maximum allowable power supply current, I_{b} represents the set maximum allowable power supply current, ξ represents the ratio of the height of the conductors to the skin depth, and N represents the identification of the conductors.

12. The device for testing the peak performance of the motor according to claim 9, wherein the setting and testing module is configured to:
set the maximum allowable power supply current of the motor and the maximum allowable power supply voltage of the motor;
calculate an electromagnetic torque and a phase voltage of the motor corresponding to each rotational speed of the motor according to a set lead angle and current test step size; and
filter out the electromagnetic torque and the phase voltage corresponding to the rotational speed at which the phase voltage exceeds the maximum allowable power supply voltage.

13. The device for testing the peak performance of the motor according to claim 12, wherein the adjustment module is configured to:
after the electromagnetic torque and the phase voltage corresponding to the rotational speed at which the phase voltage exceeds the maximum allowable power supply voltage are filtered out, when the rotational speed of the motor reaches the predetermined rotational speed, enable the set maximum allowable power supply current to decrease with an increase of the rotational speed of the motor.

14. The device for testing the peak performance of the motor according to claim 13, wherein the continuous testing module is configured to:
generate a peak torque curve of the motor representing peak torque performance of the motor based on a maximum electromagnetic torque corresponding to each remaining rotational speed; and
generate a peak power curve of the motor representing peak power performance of the motor based on a maximum power corresponding to each remaining rotational speed.

15. The device for testing the peak performance of the motor according to claim 12, wherein the setting and testing module is configured to:
set the maximum allowable power supply voltage and the maximum allowable power supply current of the motor based on current and voltage capacities of a battery and a power control unit PEU of the new energy vehicle.

16. The device for testing the peak performance of the motor according to claim 12, wherein the setting and testing module is configured to:
obtain a D-axis output voltage and a Q-axis output voltage under a rotational coordinate system corresponding to each rotational speed of the motor; and
calculate the phase voltage corresponding to the rotational speed based on the obtained D-axis output voltage and Q-axis output voltage corresponding to each rotational speed.
